(19) United States
(12) Patent Application Publication
(10) Pub. No.: US 2026/0068680 A1
(43) Pub. Date: Mar. 5, 2026

(54) ELECTROMAGNETIC COMPATIBILITY ROBUSTNESS OF DIE-TO-DIE INTERCONNECTS

(71) Applicant: Infineon Technologies Americas Corp., Ei Segundo, CA (US)

(72) Inventors: Shaowu Huang, Los Altos, CA (US); Dance WU, Palo alto, CA (US)

(73) Assignee: Infineon Technologies Americas Corp, El Segundo, CA (US)

(21) Appl. No.: 19/312,184

(22) Filed: Aug. 27, 2025

Related U.S. Application Data
(60) Provisional application No. 63/689,619, filed on Aug. 30, 2024.

(51) Int. Cl. H01L 23/552; H01L 21/50; H01L 23/498; H01L 23/64; H01L 25/16

(52) U.S. Cl. CPC H01L 23/552

(57) ABSTRACT

A system and method of improving electromagnetic compatibility robustness of die-to-die interconnects within MDMs operating in environments susceptible to EMI. The method includes providing a package substrate. The method includes disposing a first integrated circuit (IC) die on a top side of the package substrate. The method includes disposing a second IC on the top side of the package substrate. The method includes enclosing the first IC die and the second IC die with a molding component. The method includes embedding a communication bus within the package substrate and electrically coupling the communication bus between the first IC die and the second IC die. The method includes configuring the package substrate to attenuate EMI incident upon at least one of the first IC die or the second IC die, to reduce or prevent the EMI from coupling into the communication bus.

### CROSS-REFERENCE TO RELATED APPLICATIONS

This application claims the benefit of U.S. Provisional Application Ser. No. 63/689,619 entitled “Techniques for Improving EMC Robustness of Die-to-Die Interconnects,” filed Aug. 30, 2024, the disclosure of which is incorporated herein by reference in its entirety.

### TECHNICAL FIELD

The present disclosure relates generally to the multi-die modules (MDMs), and more particularly, to systems and methods of improving electromagnetic compatibility robustness of die-to-die interconnects within MDMs operating in environments susceptible to electromagnetic interference (EMI).

### BACKGROUND

Multi-die modules, or MDMs, are semiconductor packaging solutions that integrate multiple dies into a single physical unit, with the dies interconnected through die-to-die interconnects. This approach enables improved performance, reduced power consumption, and more compact designs compared to traditional single die and single chip systems. In automotive applications, for example, MDMs are used to support complex electronic systems such as control units, driver assistance technologies, and infotainment platforms. These systems often demand high bandwidth communication and low latency, which MDMs help achieve by enabling close integration of processing, memory, and specialized components. MDMs also support heterogeneous integration, allowing different types of die to operate together efficiently within a single package. Their compact form factor and performance advantages make them well suited for space constrained and thermally demanding automotive environments.

### BRIEF DESCRIPTION OF THE DRAWINGS

The present disclosure is illustrated by way of example, and not by way of limitation, in the figures of the accompanying drawings in which like reference numerals refer to similar elements and in which:

FIG. 1 illustrates an example MDM in which die-to-die connections are positioned within the package substrate, and an AC-coupling capacitor is positioned outside the package substrate, in accordance with some embodiments;

FIG. 2 illustrates an example MDM in which die-to-die connections and an AC-coupling capacitor are positioned within the package substrate, in accordance with certain embodiments;

FIG. 3 illustrates an example MDM in which die-to-die connections are positioned within the package substrate, in accordance with some embodiments;

FIG. 4 illustrates an example MDM in which die-to-die connections and an AC-coupling capacitor are positioned on a top-layer of the package substrate and a grounded shield is internal to the MDM, in accordance with some embodiments;

FIG. 5 illustrates an example MDM in which die-to-die connections are positioned on a top layer of the package substrate and a grounded shield is internal to the MDM, in accordance with certain embodiments;

FIG. 6 illustrates an example MDM in which die-to-die connections and an AC-coupling capacitor are positioned on a top-layer of the package substrate and a grounded shield is external to the MDM, in accordance with some embodiments;

FIG. 7 illustrates an example MDM in which die-to-die connections are positioned within the package substrate and an AC-coupling capacitor are positioned within a die, in accordance with some embodiments;

FIG. 8 illustrates an example automotive environment in which an MDM may be deployed, in accordance with some embodiments;

FIG. 9 is a flow diagram of a method of improving electromagnetic compatibility robustness of die-to-die interconnects within MDMs operating in environments susceptible to EMI; and

FIG. 10 is a block diagram of an example computing device that may perform one or more of the operations described herein, in accordance with some embodiments.

### DETAILED DESCRIPTION

The following description sets forth numerous specific details such as examples of specific systems, components, methods, and so forth, in order to provide a good understanding of various embodiments of the techniques described herein for improving electromagnetic compatibility robustness of die-to-die interconnects within MDMs operating in environments susceptible to EMI. It will be apparent to one skilled in the art, however, that at least some embodiments may be practiced without these specific details. In other instances, well-known components, elements, or methods are not described in detail or are presented in a simple block diagram format to avoid unnecessarily obscuring the techniques described herein. Thus, the specific details set forth hereinafter are merely exemplary. Particular implementations may vary from these exemplary details and still be contemplated to be within the scope of the present disclosure.

For simplicity of description, many embodiments described herein focus on improving electromagnetic compatibility (EMC) robustness of die-to-die interconnects within MDMs operating in EMI-prone environments. However, it is understood that these embodiments are equally applicable to multi-chip modules (MCMs), wherein the multiple dies may be replaced with multiple chips, while maintaining the same capability to enhance EMC robustness of chip-to-chip interconnects within MCMs. As used herein, a semiconductor die, in some embodiments, refers to the bare, unpackaged form of a semiconductor device, which remains exposed and therefore lacks the protective encapsulation typically provided by a molded or sealed housing. In contrast, a semiconductor chip, in some embodiments, refers to a semiconductor die that is enclosed within a protective package, which includes electrical connections, encapsulation materials, and mechanical structures necessary for integration into electronic systems.

In automotive integrated circuit packages, die-to-die interconnects facilitate high speed communication between multiple dies within a multi-die module. Due to layout constraints and system level considerations, these interconnects are often routed partially or entirely on the top surface layers of the package substrate, which are externally exposed to the surrounding electromagnetic environment. This is particularly true when the interconnects serve as channels for high-speed interfaces that utilize discrete components, such as alternating current (AC) coupling capacitors, which are also mounted on the top surface layers of the package substrate for both electrical performance and mechanical accessibility.

Surface routed interconnects and their associated components can behave as unintended antennas, making them highly susceptible to coupling external EMI under automotive EMC testing conditions. The problem is further exacerbated by the use of large passive components, such as capacitors, which are designed to meet automotive grade standards like AEC-Q200 (Automotive Electronics Council—Qualification Standard 200). Compared to consumer grade components, these larger devices exhibit higher equivalent antenna sensitivity, increasing their tendency to pick up unwanted noise. In addition to radiated immunity concerns, surface routed die-to-die interconnects can also be sources of radiated emissions, which may interfere with other systems within the vehicle or nearby electronic devices. These challenges are particularly pronounced in automotive environments where multiple wireless technologies, including Bluetooth, cellular, and Wi Fi, coexist and contribute to a high noise floor.

Existing solutions to mitigate EMI and EMC issues associated with die-to-die interconnects typically involve enclosing the entire integrated circuit package or the printed circuit board in a metal case or conductive shield. While such shielding can suppress both radiated emissions and susceptibility to external noise, these approaches may introduce additional cost, complexity, and thermal management challenges. Accordingly, there is a long-felt need for improved solutions that address the EMC vulnerabilities of die-to-die interconnects in automotive applications without compromising system performance, manufacturability, or reliability.

Aspects of the disclosure provide solutions to the above-described and other deficiencies by applying techniques at different levels of the system architecture to enhance the electromagnetic compatibility of die-to-die interconnects within MDMs, particularly in environments prone to EMI.

These techniques may be implemented at the package, system, and circuit levels, each addressing different aspects of the EMI susceptibility. At the package level, one solution involves relocating interconnects that are routed on the top surface layers of the package substrate to internal layers, thereby reducing their exposure to external EMI. In cases where passive components, such as AC coupling capacitors, are included in the die-to-die interconnect path, these components may be moved from the top surface layer to the bottom surface layer of the package substrate, which is opposite the top surface layer. This repositioning may involve the deliberate removal of a small number of non-critical functional balls of a ball gate array (BGA) to create space for the passives. Alternatively, surface-mounted AC coupling capacitors may be replaced with embedded capacitors integrated within the substrate itself. Additionally, localized shielding coatings or layers may be applied over sensitive interconnect regions, with electrical connections to the package ground, such as Voltage Source Supply (VSS) and/or Analog VSS (AVSS), to suppress EMI coupling.

At the system level, shielding structures or enclosures may be introduced to isolate high-speed interconnects from ambient EMI sources. These structures are electrically connected to the system ground, such as VSS and/or AVSS, to enhance their effectiveness in reducing susceptibility to external noise.

At the circuit level, the signaling architecture may be modified from an AC-coupled scheme to a direct-current (DC)-coupled scheme. This change eliminates the need for AC coupling capacitors and reduces the overall susceptibility of the interconnects to electromagnetic interference.

In an illustrative embodiment, an MDM includes a package substrate. The MDM also includes a first IC die disposed on a top side of the package substrate. The MDM also includes a second IC die disposed on the top side of the package substrate. The MDM also includes a molding component enclosing the first IC die and the second IC die. The MDM also includes a communication bus embedded within the package substrate and electrically coupled between the first IC die and the second IC die. The package substrate is configured to attenuate EMI incident upon at least one of the first IC die or the second IC die, to reduce or prevent the EMI from coupling into the communication bus.

In another illustrative embodiment, an MDM includes a package substrate. The MDM includes a first IC die disposed on a top side of the package substrate. The MDM includes a second IC die disposed on the top side of the package substrate. The MDM includes a molding component enclosing the first IC die and the second IC die. The MDM includes a communication bus disposed on the top of the package substrate and electrically coupled between the first IC die and the second IC die. The MDM includes a grounded shield coupled to a ground plane of the first IC die and the second IC die and configured to attenuate EMI incident upon at least one of the first IC die or the second IC die, to reduce or prevent the EMI from coupling into the communication bus.

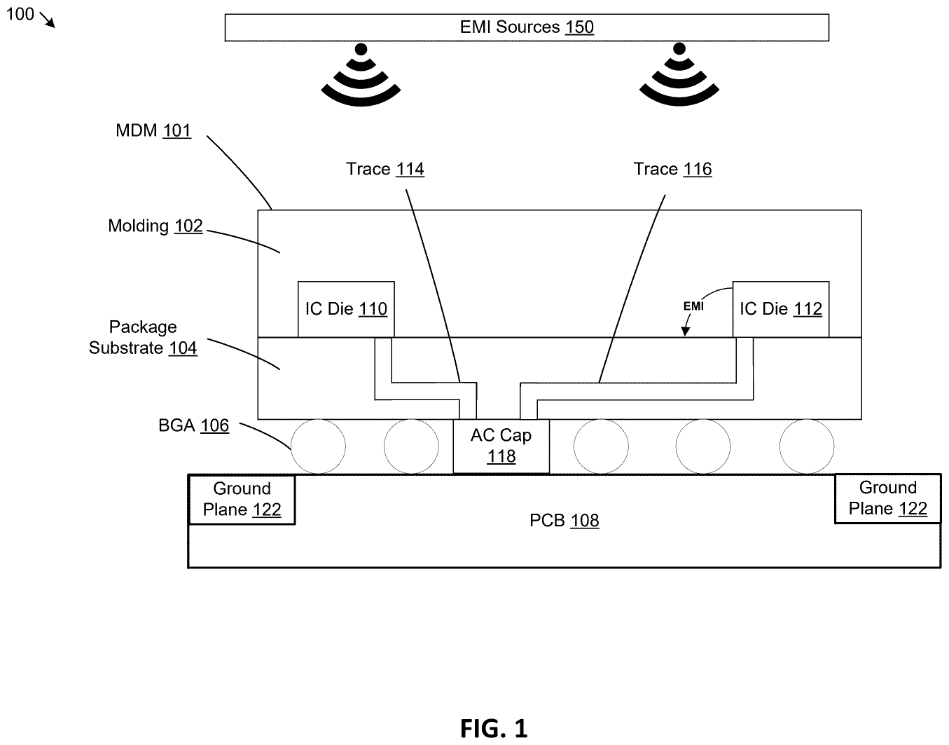

FIG. 1 illustrates a block diagram of an MDM in which die-to-die connections are positioned within a package substrate, and an AC-coupling capacitor is positioned outside the package substrate, in accordance with some embodiments. The block diagram 100 depicts an MDM 101 subjected to EMI from one or more EMI sources 150. These EMI sources 150 may include, for example, wireless communication technologies such as Bluetooth, Wi-Fi, and cellular signals, as well as other nearby electronic devices and power distribution systems. Exposure to such EMI can degrade the electrical performance of electrical components and communication paths within the MDM, potentially leading to signal integrity issues, increased error rates, or functional instability.

The MDM 101 includes a package substrate 104. A package substrate is a foundational layer within an integrated circuit package that provides mechanical support and electrical interconnection between the die or chip and the external circuitry, which may be composed of materials such as fiberglass-reinforced epoxy resin (e.g., FR-4), polyimide, or ceramic.

The MDM 101 includes IC die 110 and IC die 112, both of which are disposed on a top side of the package substrate 104. An IC die (e.g., semiconductor die) is a small rectangular piece of semiconductor material, such as silicon, that contains functional electronic circuits including transistors, capacitors, resistors, inductors, and interconnects. In some embodiments, IC die 110 may be an automotive Ethernet die configured to perform Ethernet communication functions tailored for automotive environments, supporting high-speed and reliable data transmission across in-vehicle networks to enable features such as advanced driver assistance systems (ADAS), infotainment, and vehicle-to-everything (V2X) communication. In some embodiments, IC die 112 may be configured to manage one or more operations of a vehicle (e.g., car, boat, plane, drone).

In some embodiments, IC die 112 may be configured to manage one or more vehicle (e.g., car, boat, plane, drone) operations. For example, IC die 112 may be configured as an engine control unit (ECU) to manage fuel injection, ignition timing, and air-fuel ratio; as a transmission control unit (TCU) to control gear shifting and torque management; as a brake control unit to enable anti-lock braking system (ABS) and electronic stability control (ESC); as a steering control unit to manage steering functions; as a powertrain control unit to control electric motor performance in electric vehicles; and/or as a steering control unit to manage steering functions; as a powertrain control unit to control electric motor performance in electric vehicles; and/or as a self-driving (FSD) unit to operate components associated with autonomous driving, such as vision systems (e.g., cameras, Light Detection and Ranging (LiDAR)), neural network processing systems, path planning and decision-making systems, and actuator control systems.

The MDM 101 includes a molding component 102 enclosing the IC die 110 and the IC die 112. The molding component 102 is a protective encapsulation structure formed from a dielectric molding compound, such as epoxy resin, that surrounds and secures IC die 110 and IC die 112, providing mechanical stability, environmental protection, and some electrical insulation.

The MDM 101 includes a ball gate array (BGA) 106 disposed on a bottom side of the package substrate 104, and the BGA 106 is soldered to a PCB 108. A BGA is a type of surface-mount packaging that uses an array of solder balls to create electrical and mechanical connections between the package and a printed circuit board, offering high-density interconnects and improved thermal and electrical performance compared to traditional leaded packages. The PCB 108 includes a ground plane 122.

The MDM 101 includes a capacitor 118. The capacitor 118 may conform to AEC-Q200, in that it has larger physical dimensions than standard consumer-grade capacitors and is rated for high reliability under automotive-grade conditions-such as wide operating temperature ranges, resistance to mechanical vibration, and extended service life. However, the larger physical size of these types of capacitors can make it more susceptible to EMI, as its extended surface area may behave like an unintended antenna that couples ambient EMI into signal paths or traces of the MDM 101.

To mitigate EMI produced by EMI sources 150 and IC die 112, capacitor 118 is disposed on the bottom side of the package substrate 104. This placement allows the package substrate 104 to shield the capacitor 118 from the EMI.

The MDM 101 includes die-to-die connections (sometimes collectively referred to as signal paths or a communication bus) that are embedded within the package substrate 104 and used to electrically connect capacitor 118 in series between IC die 110 and IC die 112. Specifically, the MDM 101 includes a trace 114 electrically coupling a communication port of IC die 110 and a first terminal of the capacitor 118, and a trace 116 electrically coupling a communication port of IC die 112 and a second terminal of the capacitor 118.

The communication ports of IC die 110 and IC die 112, which are electrically coupled via traces 114 and 116 and capacitor 118, may implement high-speed interfaces such as Universal Chiplet Interconnect Express (UCIe), High Bandwidth Memory (HBM), or Bunch of Wires (BoW). Capacitor 118 AC-couples the signal path between these ports, enabling robust high-speed communication across the die-to-die connections. In some embodiments, the communication path may be further configured to support automotive Ethernet, such as IEEE (Institute of Electrical and Electronics Engineers) 802.3bw (100BASE-T1) or IEEE 802.3 bp (1000BASE-T1).

Notably, embedding the die-to-die connections—formed by traces 114 and 116—within package substrate 104 enables the substrate to shield both the traces and capacitor 118 from EMI emitted by EMI sources 150 and IC die 112 (as shown in FIG. 1). By shielding both capacitor 118 and the embedded traces 114 and 116, the package substrate 104 attenuates EMI incident upon IC die 110 and IC die 112, and reduces the likelihood that such EMI will couple into traces 114 and 116. This shielding helps preserve signal integrity across the die-to-die connections and enhances the overall EMI robustness of the MDM 101.

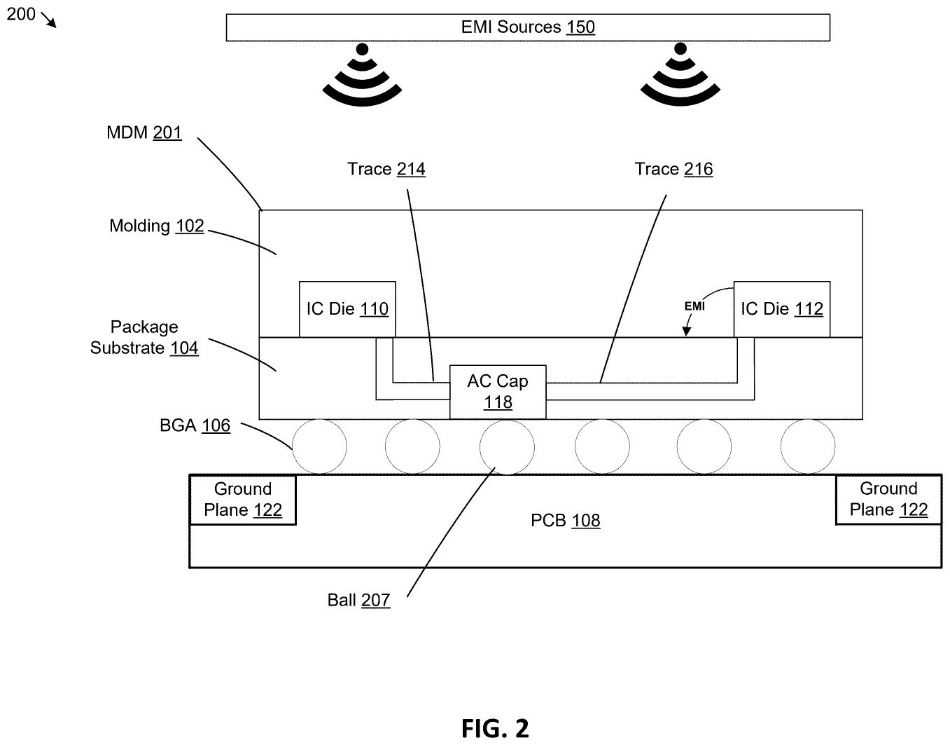

FIG. 2 illustrates a block diagram of an MDM in which die-to-die connections and an AC-coupling capacitor are positioned within the package substrate, in accordance with certain embodiments. The MDM 201 shown in FIG. 2 is similarly configured to the MDM 101 of FIG. 1, including IC die 110 and IC die 112 disposed on a top side of a package substrate 104, a molding component 102 enclosing both IC die, and a BGA 106 disposed on a bottom side of the package substrate 104.

However, unlike the configuration in FIG. 1, the capacitor 118 in FIG. 2 is embedded within the package substrate 104 rather than being disposed on its bottom side. The MDM 201 includes a trace 214 electrically coupling IC die 110 and a first terminal of the capacitor 118, and a trace 216 electrically coupling IC die 112 and a second terminal of the capacitor 118.

Embedding the capacitor 118 within the package substrate 204 not only frees up space for ball 207 to be added to BGA 106, but also provides additional shielding from EMI emitted by EMI sources 150 and IC die 112. This configuration further reduces the likelihood of EMI coupling into capacitor 118 or the die-to-die traces, thereby enhancing signal integrity and improving the overall EMI robustness of the MDM 201.

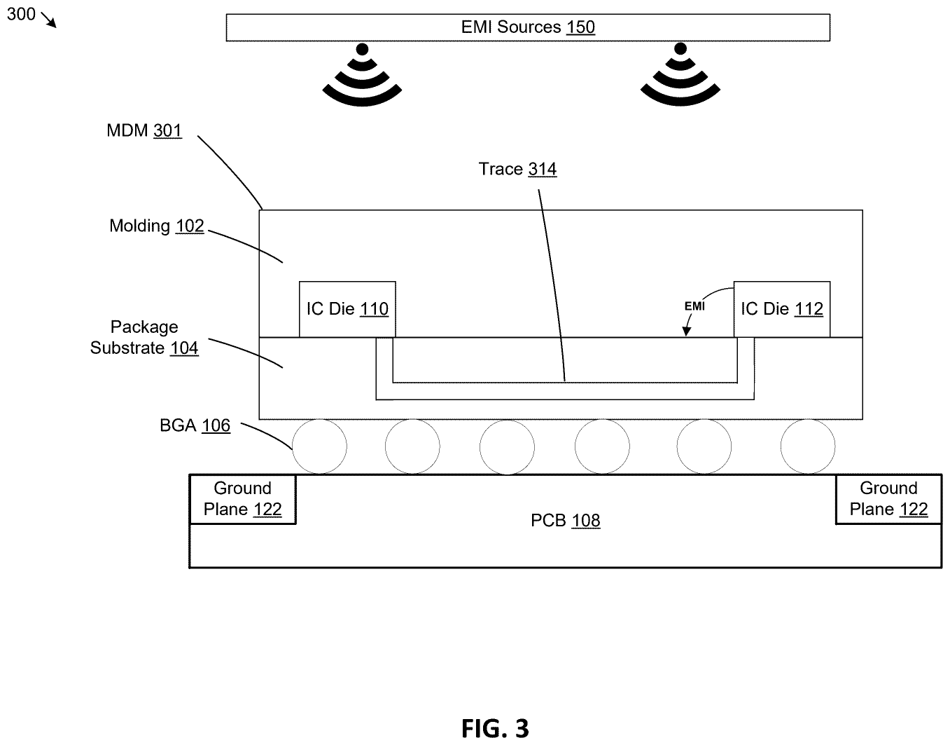

FIG. 3 illustrates a block diagram of an MDM in which die-to-die connections are positioned within the package substrate, in accordance with some embodiments. The MDM 301 shown in FIG. 3 is similarly configured to the MDM 201 of FIG. 2, including IC die 110 and IC die 112 disposed on a top side of a package substrate 104, and a molding component 102 enclosing both IC die. However, unlike the configuration in FIG. 2, the die-to-die connection between IC die 110 and IC die 112 is direct-coupled rather than AC-coupled, thereby eliminating capacitor 118. Specifically, the MDM 301 includes a trace 314 electrically coupling a communication port of IC die 110 to a communication port of IC die 112.

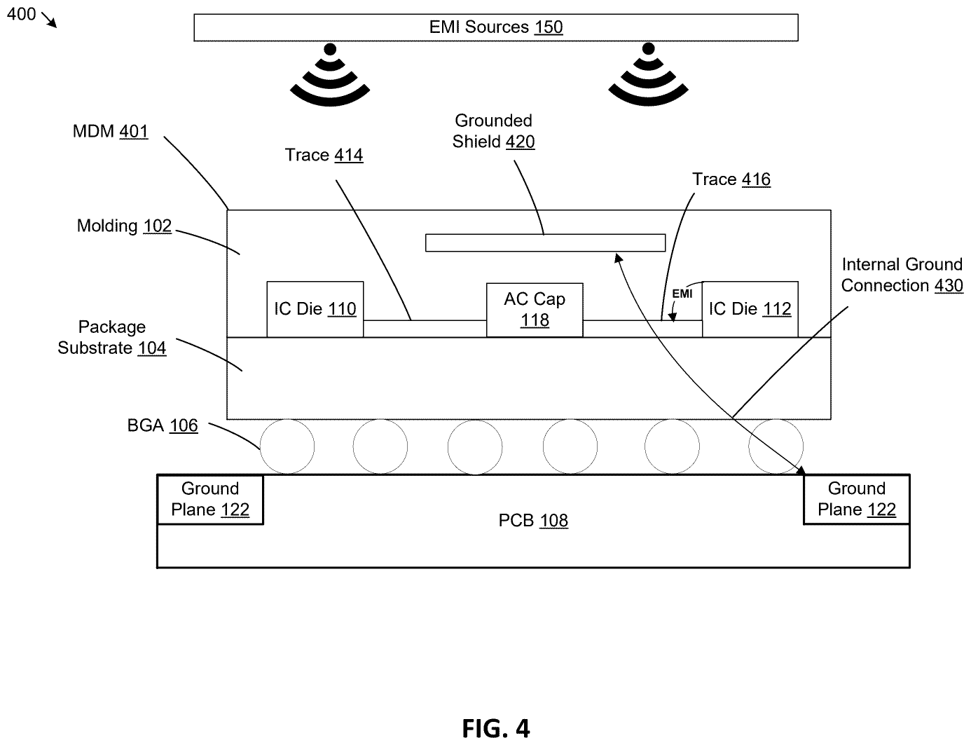

FIG. 4 illustrates a block diagram of an MDM in which die-to-die connections and an AC-coupling capacitor are positioned on a top-layer of the package substrate and a grounded shield is internal to the MDM, in accordance with some embodiments. The MDM 401 includes IC die 110 and IC die 112 disposed on a top side of a package substrate 104, a molding component 102 enclosing both IC die, and a BGA 106 disposed on a bottom side of the package substrate 104.

The die-to-die connection between IC die 110 and IC die 112 is established by traces disposed on a top surface of the package substrate 104. Specifically, trace 414 electrically couples a communication port of the IC die 110 and a first terminal of capacitor 118, and trace 416 electrically couples a communication port of the IC die 112 and a second terminal of capacitor 118.

To mitigate the effects of EMI emitted by EMI source 150 and IC die 112 on the die-to-die connection, a grounded shield 420 is embedded within molding component 102 at a position that is vertically offset from the die-to-die connection to provide localized shielding for the die-to-die connection. Grounded shield 420 is electrically coupled to a ground plane 122 of PCB 108 via an internal connection that passes through package substrate 104.

As shown in FIG. 4, the grounded shield 420 extends along less than an entire length of the die-to-die connection. The grounded shield has a length corresponding to a vertical distance between the grounded shield 420 and the die-to-die connection, such that greater vertical distances correspond to greater shield lengths.

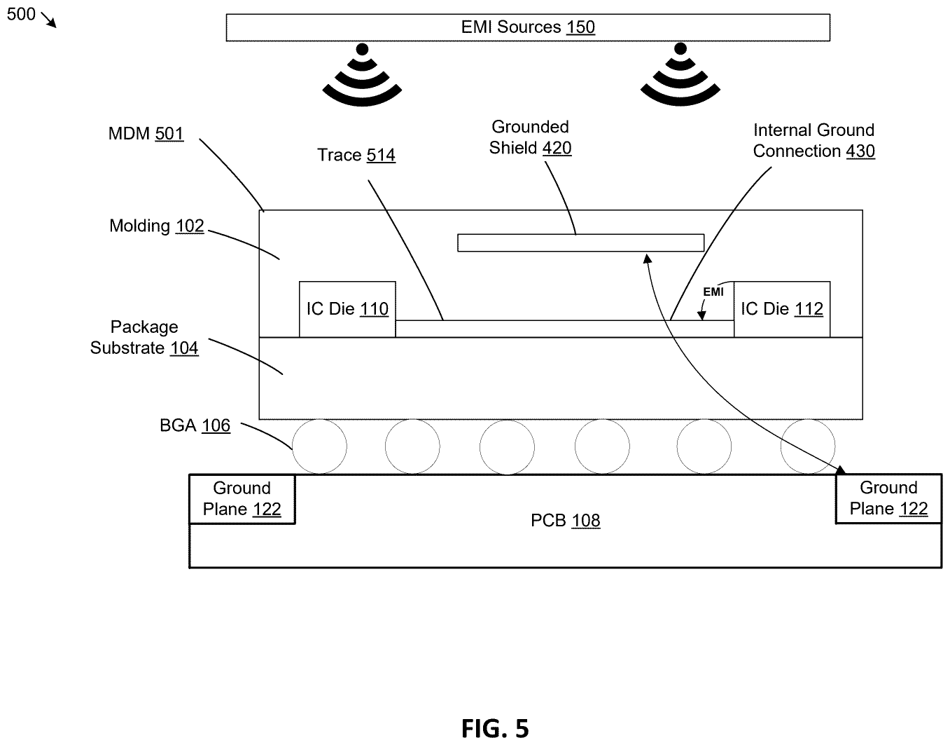

FIG. 5 illustrates a block diagram of an MDM in which die-to-die connections are positioned on a top layer of the package substrate and a grounded shield is internal to the MDM, in accordance with certain embodiments. The MDM 501 shown in FIG. 5 is similarly configured to the MDM 401 of FIG. 4, including IC die 110 and IC die 112 disposed on a top side of a package substrate 104, a molding component 102 enclosing both IC die, and a BGA 106 disposed on a bottom side of the package substrate 104.

However, unlike the configuration in FIG. 4, the die-to-die connection between IC die 110 and IC die 112 is direct-coupled rather than AC-coupled, thereby eliminating capacitor 118. Specifically, the MDM 501 includes a trace 514 electrically coupling a communication port of IC die 110 to a communication port of IC die 112.

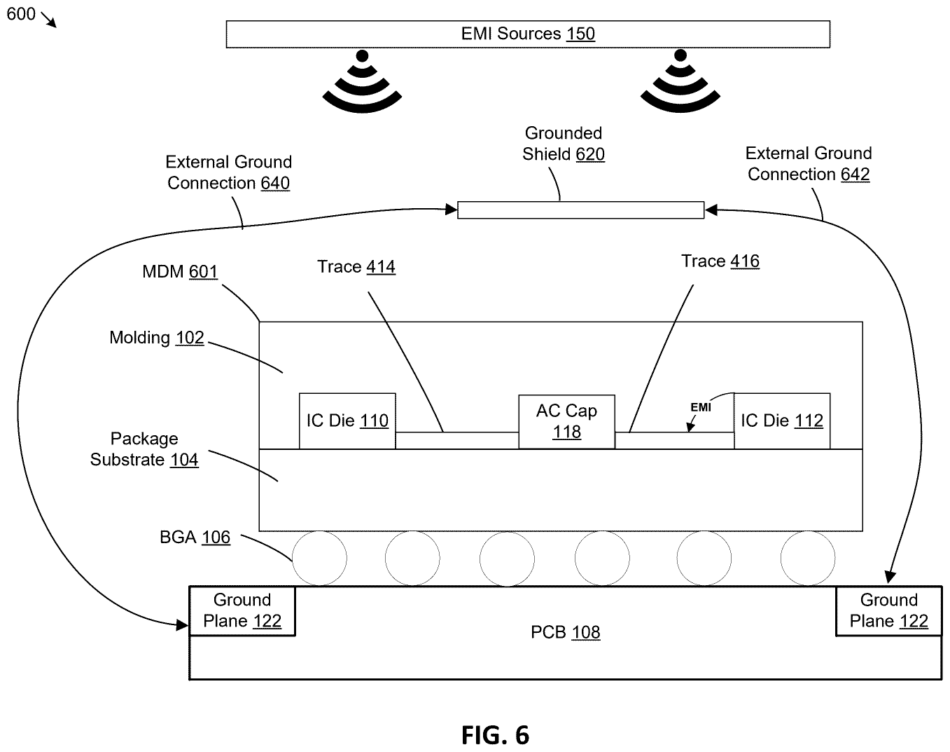

FIG. 6 illustrates a block diagram of an MDM in which die-to-die connections and an AC-coupling capacitor are positioned on a top-layer of the package substrate and a grounded shield is external to the MDM, in accordance with some embodiments. The MDM 601 shown in FIG. 6 is similarly configured to the MDM 401 of FIG. 4, including IC die 110 and IC die 112 disposed on a top side of a package substrate 104, a molding component 102 enclosing both IC die, a BGA 106 disposed on a bottom side of the package substrate 104, and an AC-coupled die-to-die connection between the IC die established via trace 414, capacitor 118, and trace 416.

However, unlike the configuration in FIG. 4, the grounded shield 620 is positioned above the MDM 601, between the EMI sources 150 and the MDM 601, to provide localized shielding for the die-to-die connection. In some embodiments, the grounded shield 620 encloses the molding component 102 and the package substrate 104 of MDM 601. Grounded shield 620 is electrically coupled to a ground plane 122 of PCB 108 via an external connection that does not pass through package substrate 104.

In some embodiments, capacitor 118 may be removed to establish a DC-coupled die-to-die connection between IC die 110 and IC die 112.

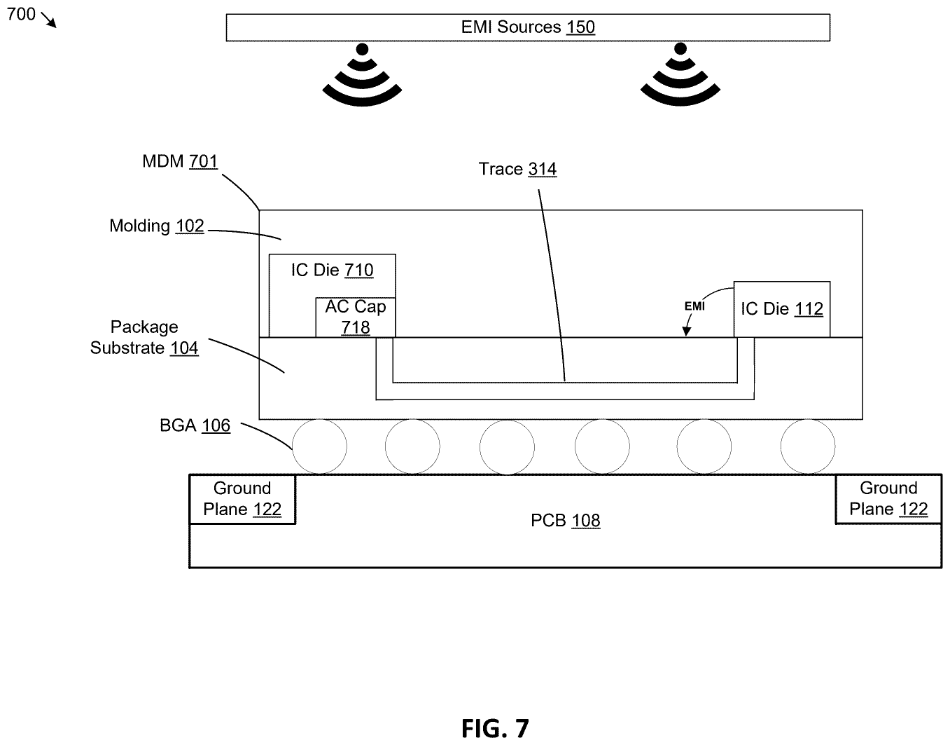

FIG. 7 illustrates a block diagram of an MDM in which die-to-die connections are positioned within the package substrate and an AC-coupling capacitor are positioned within a die, in accordance with some embodiments. The MDM 701 shown in FIG. 7 is similarly configured to the MDM 301 of FIG. 3, including IC die 110 and IC die 112 disposed on a top side of a package substrate 104, a molding component 102 enclosing both IC die, a BGA 106 disposed on a bottom side of the package substrate 104, and a die-to-die connection between the IC die established via trace 314 that is embedded in package substrate 104.

However, unlike the configuration in FIG. 3, IC die 710 includes capacitor 718, such that the die-to-die connection established via trace 314 is AC-coupled rather than DC-coupled.

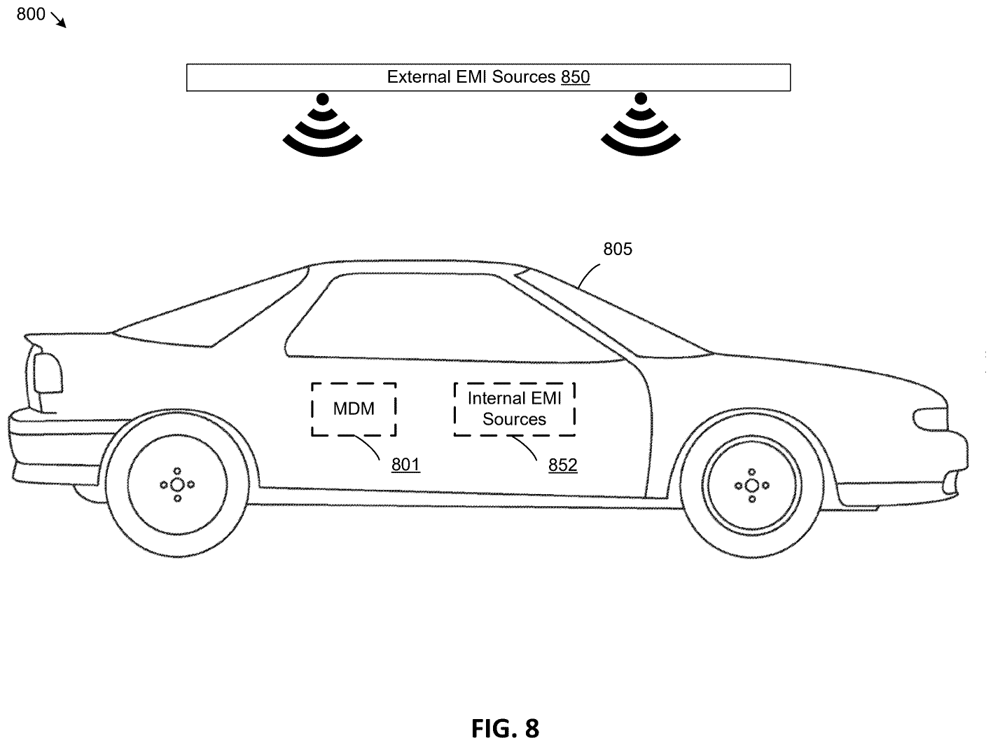

FIG. 8 illustrates an example automotive environment in which an MDM may be deployed, in accordance with some embodiments. Environment 800 includes a car 805 that incorporates MDM 801, which may correspond to any MDM discussed herein. MDM 801 is subjected to EMI generated from within the car 805 by internal EMI sources 852 and from EMI generated from outside the car 805 by external EMI sources 850.

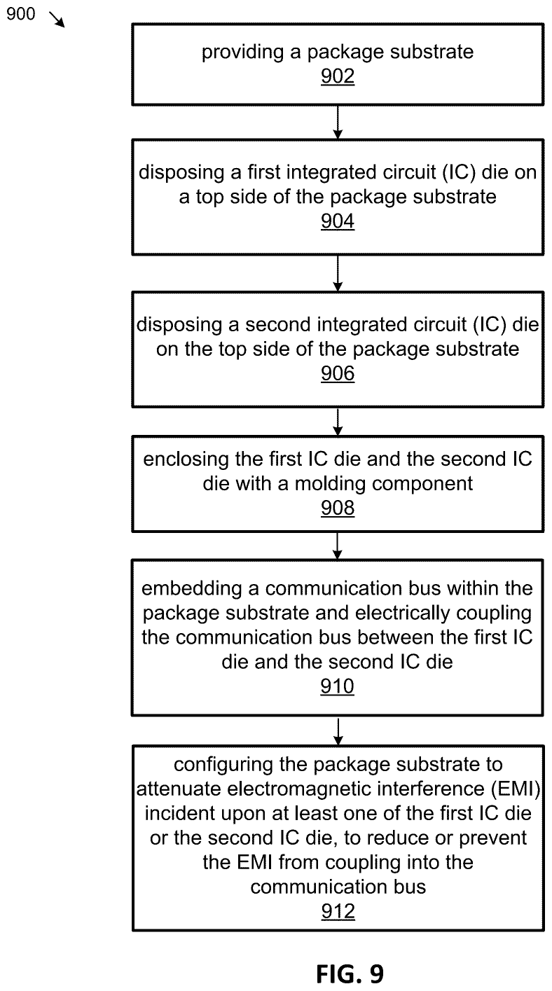

FIG. 9 is a flow diagram of a method of improving electromagnetic compatibility robustness of die-to-die interconnects within MDMs operating in environments susceptible to EMI. Although the operations are depicted in FIG. 9 as integral operations in a particular order for purposes of illustration, in other implementations, one or more operations, or portions thereof, are performed in a different order, or overlapping in time, in series or parallel, or are omitted, or one or more additional operations are added, or the method is changed in some combination of ways. In some embodiments, the method 900 may be performed by processing logic that includes hardware (e.g., circuitry, dedicated logic, programmable logic, microcode, etc.), firmware, or a combination thereof. In some embodiments, some or all operations of method 900 may be performed using semiconductor manufacturing equipment.

As shown in FIG. 9, the method 900 includes the operation 902 of providing a package substrate. The method 900 includes the operation 904 of disposing a first integrated circuit (IC) die on a top side of the package substrate. The method 900 includes the operation 906 of disposing a second integrated circuit (IC) die on the top side of the package substrate. The method 900 includes the operation 908 of enclosing the first IC die and the second IC die with a molding component. The method 900 includes the operation 910 of embedding a communication bus within the package substrate and electrically coupling the communication bus between the first IC die and the second IC die. The method 900 includes the operation 912 of configuring the package substrate to attenuate electromagnetic interference (EMI) incident upon at least one of the first IC die or the second IC die, to reduce or prevent the EMI from coupling into the communication bus.

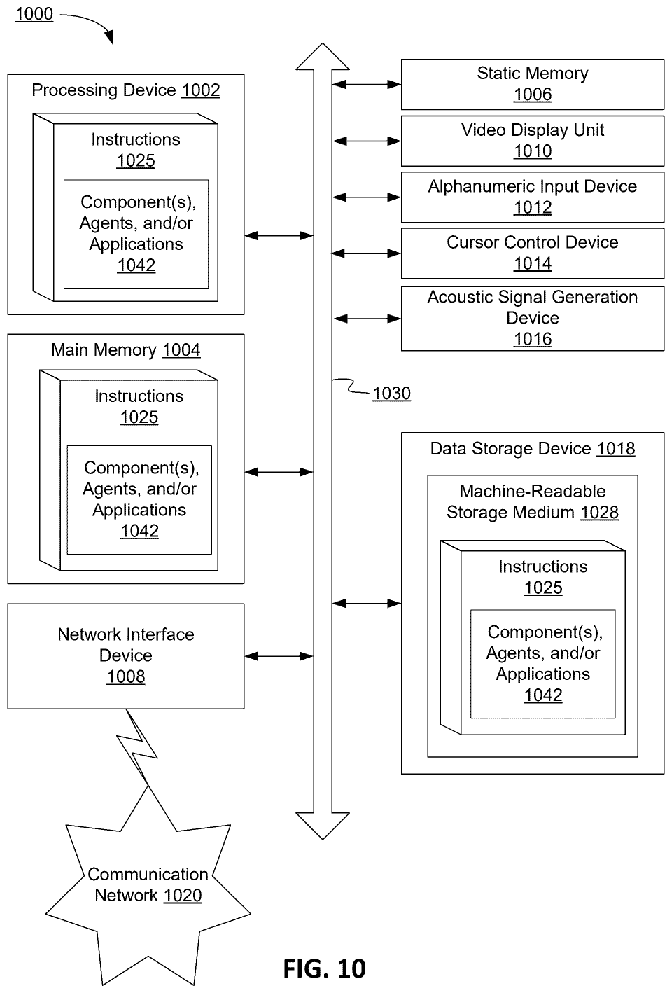

FIG. 10 is a block diagram of an example computing device that may perform one or more of the operations described herein, in accordance with some embodiments. Computing device 1000 may be connected to other computing devices in a LAN, an intranet, an extranet, and/or the Internet. The computing device may operate in the capacity of a server machine in client-server network environment or in the capacity of a client in a peer-to-peer network environment. The computing device may be provided by a personal computer (PC), a set-top box (STB), a server, a network router, switch or bridge, or any machine capable of executing a set of instructions (sequential or otherwise) that specify actions to be taken by that machine. Further, while only a single computing device is illustrated, the term “computing device” shall also be taken to include any collection of computing devices that individually or jointly execute a set (or multiple sets) of instructions to perform the methods discussed herein.

The example computing device 1000 may include a processing device (e.g., a general-purpose processor, a PLD, etc.) 1002, a main memory 1004 (e.g., synchronous dynamic random-access memory (DRAM), read-only memory (ROM)), a static memory 1006 (e.g., flash memory and a data storage device 1018), which may communicate with each other via a bus 1030.

Processing device 1002 may be provided by one or more general-purpose processing devices such as a microprocessor, central processing unit, or the like. In an illustrative example, processing device 1002 may include a complex instruction set computing (CISC) microprocessor, reduced instruction set computing (RISC) microprocessor, very long instruction word (VLIW) microprocessor, or a processor implementing other instruction sets or processors implementing a combination of instruction sets. Processing device 1002 may also include one or more special-purpose processing devices such as an application specific integrated circuit (ASIC), a field programmable gate array (FPGA), a digital signal processor (DSP), network processor, or the like. The processing device 1002 may be configured to execute the operations described herein, in accordance with one or more aspects of the present disclosure, for performing the operations and steps discussed herein.

Computing device 1000 may further include a network interface device 1008 which may communicate with a communication network 1020. The computing device 1000 also may include a video display unit 1010 (e.g., a liquid crystal display (LCD) or a cathode ray tube (CRT)), an alphanumeric input device 1012 (e.g., a keyboard), a cursor control device 1014 (e.g., a mouse) and an acoustic signal generation device 1016 (e.g., a speaker). In one embodiment, video display unit 1010, alphanumeric input device 1012, and cursor control device 1014 may be combined into a single component or device (e.g., an LCD touch screen).

Data storage device 1018 may include a computer-readable storage medium 1028 on which may be stored one or more sets of instructions 1025 that may include instructions for one or more components/programs/applications 1042 for carrying out the operations (e.g., operations of method 900 in FIG. 9) described herein, in accordance with one or more aspects of the present disclosure. Instructions 1025 may also reside, completely or at least partially, within main memory 1004 and/or within processing device 1002 during execution thereof by computing device 1000, main memory 1004 and processing device 1002 also constituting computer-readable media. The instructions 1025 may further be transmitted or received over a communication network 1020 via network interface device 1008.

While computer-readable storage medium 1028 is shown in an illustrative example to be a single medium, the term “computer-readable storage medium” should be taken to include a single medium or multiple media (e.g., a centralized or distributed database and/or associated caches and servers) that store the one or more sets of instructions. The term “computer-readable storage medium” shall also be taken to include any medium that is capable of storing, encoding or carrying a set of instructions for execution by the machine and that cause the machine to perform the methods described herein. The term “computer-readable storage medium” shall accordingly be taken to include, but not be limited to, solid-state memories, optical media and magnetic media.

Example 1 is an MDM, including: a package substrate; a first integrated circuit (IC) die disposed on a top side of the package substrate; a second integrated circuit (IC) die disposed on the top side of the package substrate; a molding component enclosing the first IC die and the second IC die; and a communication bus embedded within the package substrate and electrically coupled between the first IC die and the second IC die, wherein the package substrate is configured to attenuate electromagnetic interference (EMI) incident upon at least one of the first IC die or the second IC die, to reduce or prevent the EMI from coupling into the communication bus.

Example 2 is the MDM of Example 1, further including a ball gate array (BGA) disposed on a bottom side of the package substrate; and a capacitor disposed on the bottom side of the package substrate and electrically connected in series with the communication bus between the first IC die and the second IC die.

Example 3 is the MDM of Example 2, wherein the capacitor is disposed in a region of the bottom side of the package substrate from which one or more balls of the BGA are omitted.

Example 4 is the MDM of Example 1, further including a capacitor embedded within the package substrate and electrically connected in series with the communication bus between the first IC die and the second IC die.

Example 5 is the MDM of Example 1, further including a capacitor embedded within the first IC die and electrically connected in series with the communication bus between the first IC die and the second IC die.

Example 6 is the MDM of Example 1, wherein the communication bus is configured to support at least one of: a Universal Chiplet Interconnect Express (UCIe) interface, a High Bandwidth Memory (HBM) interface, or a Bunch of Wires (BoW) physical interface

Example 7 is the MDM of Example 1, wherein the first IC die is configured to provide Ethernet communication functionality, and the second IC die is configured to manage one or more vehicle operations.

Example 8 is an MDM including a package substrate; a first integrated circuit (IC) die disposed on a top side of the package substrate; a second integrated circuit (IC) die disposed on the top side of the package substrate; a molding component enclosing the first IC die and the second IC die; a communication bus disposed on the top of the package substrate and electrically coupled between the first IC die and the second IC die; and a grounded shield coupled to a ground plane of the first IC die and the second IC die and configured to attenuate electromagnetic interference (EMI) incident upon at least one of the first IC die or the second IC die, to reduce or prevent the EMI from coupling into the communication bus.

Example 9 is the MDM of Example 8, wherein the grounded shield encloses the molding component and the package substrate.

Example 10 is the MDM of Example 8, wherein the grounded shield is embedded within the molding component at a position that is vertically offset from the communication bus, the grounded shield extending along less than an entire length of the communication bus.

Example 11 is the MDM of Example 10, further including a capacitor disposed on the top of the package substrate and electrically connected in series with the communication bus between the first IC die and the second IC die.

Example 12 is the MDM of Example 8, wherein the grounded shield has a length corresponding to a vertical distance between the grounded shield and the communication bus, wherein greater vertical distances correspond to greater shield lengths.

Example 13 is the MDM of Example 8, wherein the communication bus is configured to support at least one of: a Universal Chiplet Interconnect Express (UCIe) interface, a High Bandwidth Memory (HBM) interface, or a Bunch of Wires (BoW) physical interface.

Example 14 is the MDM of Example 8, wherein the first IC die is configured to provide Ethernet communication functionality, and the second IC die is configured to manage one or more vehicle operations.

In the above description, some portions of the detailed description are presented in terms of algorithms and symbolic representations of operations on analog signals and/or digital signals or data bits within a non-transitory storage medium. These algorithmic descriptions and representations are the means used by those skilled in the data processing arts to most effectively convey the substance of their work to others skilled in the art. An algorithm is here and generally, conceived to be a self-consistent sequence of steps leading to a desired result. The steps are those requiring physical manipulations of physical quantities. Usually, though not necessarily, these quantities take the form of electrical or magnetic signals capable of being stored, transferred, combined, compared and otherwise manipulated. It has proven convenient at times, principally for reasons of common usage, to refer to these signals as bits, values, elements, symbols, characters, terms, numbers, or the like.

Reference in the description to “an embodiment,” “one embodiment,” “an example embodiment,” “some embodiments,” and “various embodiments” means that a particular feature, structure, step, operation, or characteristic described in connection with the embodiment(s) is included in at least one embodiment of the disclosure. Further, the appearances of the phrases “an embodiment,” “one embodiment,” “an example embodiment,” “some embodiments,” and “various embodiments” in various places in the description do not necessarily all refer to the same embodiment(s).

The description includes references to the accompanying drawings, which form a part of the detailed description. The drawings show illustrations in accordance with exemplary embodiments. These embodiments, which may also be referred to herein as “examples,” are described in enough detail to enable those skilled in the art to practice the embodiments of the claimed subject matter described herein. The embodiments may be combined, other embodiments may be utilized, or structural, logical, and electrical changes may be made without departing from the scope and spirit of the claimed subject matter. The embodiments described herein are not intended to limit the scope of the subject matter but rather to enable one skilled in the art to practice, make, and/or use the subject matter.

It should be borne in mind, however, that all of these and similar terms are to be associated with the appropriate physical quantities and are merely convenient labels applied to these quantities. Unless specifically stated otherwise as apparent from the above discussion, it is appreciated that throughout the description, discussions utilizing terms such as “receiving,” “determining,” “generating,” “providing,” “maintaining,” “charging,” or the like, refer to the actions and processes of an integrated circuit (IC) controller, or similar electronic device, that manipulates and transforms data represented as physical (e.g., electronic) quantities within the controller's registers and memories into other data similarly represented as physical quantities within the controller memories or registers or other such information non-transitory storage medium.

The words “example” or “exemplary” are used herein to mean serving as an example, instance, or illustration. Any aspect or design described herein as “example’ or “exemplary” is not necessarily to be construed as preferred or advantageous over other aspects or designs. Rather, use of the words “example” or “exemplary” is intended to present concepts in a concrete fashion. As used in this application, the term “or” is intended to mean an inclusive “or” rather than an exclusive “or.” That is, unless specified otherwise, or clear from context, “X includes A or B” is intended to mean any of the natural inclusive permutations. That is, if X includes A; X includes B; or X includes both A and B, then “X includes A or B” is satisfied under any of the foregoing instances. In addition, the articles “a” and “an” as used in this application and the appended claims should generally be construed to mean “one or more” unless specified otherwise or clear from context to be directed to a singular form. Moreover, use of the term “an embodiment” or “one embodiment” or “an embodiment” or “one embodiment” throughout is not intended to mean the same embodiment or embodiment unless described as such.

Embodiments described herein may also relate to an apparatus (e.g., such as an AC-DC converter, and/or an ESD protection system/circuit) for performing the operations herein. This apparatus may be specially constructed for the required purposes, or it may include firmware or hardware logic selectively activated or reconfigured by the apparatus. Such firmware may be stored in a non-transitory computer-readable storage medium, such as, but not limited to, read-only memories (ROMs), random access memories (RAMs), EPROMS, EEPROMs, flash memory, or any type of media suitable for storing electronic instructions. The term “computer-readable storage medium” should be taken to include a single medium or multiple media that store one or more sets of instructions. The term “computer-readable medium” shall also be taken to include any medium that is capable of storing, encoding, or carrying a set of instructions for execution by the machine and that causes the machine to perform any one or more of the methodologies of the present embodiments. The term “computer-readable storage medium” shall accordingly be taken to include, but not be limited to, solid-state memories, optical media, magnetic media, any medium that is capable of storing a set of instructions for execution by the machine and that causes the machine to perform any one or more of the methodologies of the present embodiments.

The above description sets forth numerous specific details such as examples of specific systems, components, methods, and so forth, to provide a good understanding of several embodiments of the present disclosure. It is to be understood that the above description is intended to be illustrative and not restrictive. Many other embodiments will be apparent to those of skill in the art upon reading and understanding the above description. The scope of the disclosure should, therefore, be determined with reference to the appended claims, along with the full scope of equivalents to which such claims are entitled.

What is claimed is:

1. A multi-die module (MDM), comprising:
a package substrate;
a first integrated circuit (IC) die disposed on a top side of the package substrate;
a second integrated circuit (IC) die disposed on the top side of the package substrate;
a molding component enclosing the first IC die and the second IC die; and
a communication bus embedded within the package substrate and electrically coupled between the first IC die and the second IC die,
wherein the package substrate is configured to attenuate electromagnetic interference (EMI) incident upon at least one of the first IC die or the second IC die, to reduce or prevent the EMI from coupling into the communication bus.

2. The MDM of claim 1, further comprising:
a ball gate array (BGA) disposed on a bottom side of the package substrate; and
a capacitor disposed on the bottom side of the package substrate and electrically connected in series with the communication bus between the first IC die and the second IC die.

3. The MDM of claim 2, wherein the capacitor is disposed in a region of the bottom side of the package substrate from which one or more balls of the BGA are omitted.

4. The MDM of claim 1, further comprising:
a capacitor embedded within the package substrate and electrically connected in series with the communication bus between the first IC die and the second IC die.

5. The MDM of claim 1, further comprising:
a capacitor embedded within the first IC die and electrically connected in series with the communication bus between the first IC die and the second IC die.

6. The MDM of claim 1, wherein the communication bus is configured to support at least one of: a Universal Chiplet Interconnect Express (UCIe) interface, a High Bandwidth Memory (HBM) interface, or a Bunch of Wires (BoW) physical interface.

7. The MDM of claim 1, wherein the first IC die is configured to provide Ethernet communication functionality, and the second IC die is configured to manage one or more vehicle operations.

8. A multi-die module (MDM), comprising:
a package substrate;
a first integrated circuit (IC) die disposed on a top side of the package substrate;
a second integrated circuit (IC) die disposed on the top side of the package substrate;
a molding component enclosing the first IC die and the second IC die;
a communication bus disposed on the top of the package substrate and electrically coupled between the first IC die and the second IC die; and
a grounded shield coupled to a ground plane of the first IC die and the second IC die and configured to attenuate electromagnetic interference (EMI) incident upon at least one of the first IC die or the second IC die, to reduce or prevent the EMI from coupling into the communication bus.

9. The MDM of claim 8, wherein the grounded shield encloses the molding component and the package substrate.

10. The MDM of claim 8, wherein the grounded shield is embedded within the molding component at a position that is vertically offset from the communication bus, the grounded shield extending along less than an entire length of the communication bus.

11. The MDM of claim 10, further comprising:
a capacitor disposed on the top of the package substrate and electrically connected in series with the communication bus between the first IC die and the second IC die.

12. The MDM of claim 10, wherein the grounded shield has a length corresponding to a vertical distance between the grounded shield and the communication bus, wherein greater vertical distances correspond to greater shield lengths.

13. The MDM of claim 8, wherein the communication bus is configured to support at least one of: a Universal Chiplet Interconnect Express (UCIe) interface, a High Bandwidth Memory (HBM) interface, or a Bunch of Wires (BoW) physical interface.

14. The MDM of claim 8, wherein the first IC die is configured to provide Ethernet communication functionality, and the second IC die is configured to manage one or more vehicle operations.

15. A method, comprising:
providing a package substrate;
disposing a first integrated circuit (IC) die on a top side of the package substrate;
disposing a second IC die on the top side of the package substrate;
enclosing the first IC die and the second IC die with a molding component;
embedding a communication bus within the package substrate and electrically coupling the communication bus between the first IC die and the second IC die; and
configuring the package substrate to attenuate electromagnetic interference (EMI) incident upon at least one of the first IC die or the second IC die, to reduce or prevent the EMI from coupling into the communication bus.

16. The method of claim 15, further comprising:
disposing a ball grid array (BGA) on a bottom side of the package substrate;
disposing a capacitor on the bottom side of the package substrate; and
electrically connecting the capacitor in series with the communication bus between the first IC die and the second IC die.

17. The method of claim 15, further comprising:
embedding a capacitor within the package substrate; and
electrically connecting the capacitor in series with the communication bus between the first IC die and the second IC die.

18. The method of claim 15, further comprising:
embedding a capacitor within the first IC die; and
electrically connecting the capacitor in series with the communication bus between the first IC die and the second IC die.

19. The method of claim 15, further comprising:
configuring the communication bus to support at least one of: a Universal Chiplet Interconnect Express (UCIe) interface, a High Bandwidth Memory (HBM) interface, or a Bunch of Wires (BoW) physical interface.

20. The method of claim 15, further comprising:
configuring the first IC die to provide Ethernet communication functionality; and
configuring the second IC die to manage one or more vehicle operations.
